(19) United States
(12) Patent Application Publication
(10) Pub. No.: US 2026/0229276 A1
(43) Pub. Date: Aug. 6, 2026

(54) MEMORY DEVICE GENERATING TRIMMED BULK VOLTAGE FOR EACH DIE

(71) Applicant: SK hynix Inc., Icheon-si Gyeonggi-do (KR)

(72) Inventors: Se Jun HAN, Icheon-si Gyeonggi-do (KR); Tae Ho KIM, Icheon-si Gyeonggi-do (KR); Dong Ju YANG, Icheon-si Gyeonggi-do (KR); Hyeon Jin YANG, Icheon-si Gyeonggi-do (KR)

(73) Assignee: SK hynix Inc., Icheon-si Gyeonggi-do (KR)

(21) Appl. No.: 19/240,634

(22) Filed: Jun. 17, 2025

(30) Foreign Application Priority Data
Jan. 20, 2025 (KR) 10-2025-0008383

(51) Int. Cl. G11C 11/4074; H01L 25/065; H01L 25/18; H10B 80/00

(52) U.S. Cl. CPC G11C 11/4074; H10B 80/00; H10W 90/00; H10W 90/291; H10W 90/297; H10W 90/722; H10W 90/724

(57) ABSTRACT

A memory device includes a base die and a plurality of core dies stacked over the base die, each including an internal circuit configured to perform an internal operation and a bulk voltage control circuit configured to generate a bulk voltage. The internal circuit includes at least one MOS transistor configured to operate by receiving the bulk voltage that is adjusted based on an internal temperature of each of the plurality of core dies.

### CROSS REFERENCE TO RELATED APPLICATION

The present application claims priority under 35 U.S.C. § 119 (a) to Korean Patent Application No. 10-2025-0008383, filed in the Korean Intellectual Property Office on Jan. 20, 2025, the entire contents of which application is incorporated herein by reference.

### BACKGROUND

### 1. Technical Field

The present disclosure relates to memory devices, including but not limited to memory devices generating a voltage.

### 2. Related Art

Stack memory systems, such as high bandwidth memory (HBM), are used in a wide range of applications due to high bandwidth. Unlike existing memory systems using a parallel data bus, the stack memory system includes a stack memory device including a base die and core dies interconnected by through silicon vias (TSVs). The stack memory device includes a physical interface, such as a physical layer, for communication with a processor. The physical layer is designed for high speed data transfer and efficient communication.

In general, semiconductor memory devices generate and use internal voltages for internal operation by using a source voltage VDD received from outside the semiconductor device and a ground voltage VSS. The voltage level of the internal voltage changes depending on a change in the voltage level of the source voltage VDD received from outside the semiconductor device and a change in a process, voltage, temperature (PVT) during an operation including generating the internal voltage.

### SUMMARY

In an embodiment, a memory device may include a plurality of core dies stacked over a base die. Each of the plurality of core dies includes an internal circuit configured to perform an internal operation. The internal circuit includes at least one metal oxide semiconductor (MOS) transistor that operates by receiving a bulk voltage. Each of the plurality of core dies further includes a bulk voltage control circuit configured to generate the bulk voltage that is adjusted based on an internal temperature of each of the plurality of core dies.

In an embodiment, a memory device may include a first core die stacked over a base die, configured to generate a first bulk voltage at a voltage level that varies based on a first process condition, and configured to supply the first bulk voltage to a body of at least one first metal oxide semiconductor (MOS) transistor included in a first internal circuit, and a second core die stacked over the first core die, configured to generate a second bulk voltage at a voltage level that varies according to a second process condition, and configured to supply the second bulk voltage to a body of at least one second MOS transistor included in a second internal circuit.

### BRIEF DESCRIPTION OF THE DRAWINGS

FIG. 1 illustrates a construction of a stack memory system according to an embodiment of the present disclosure.

FIG. 2 illustrates a construction of a plurality of core dies according to an embodiment of the present disclosure.

FIG. 3 illustrates a construction of a bulk voltage control circuit according to an embodiment of the present disclosure.

FIG. 4 illustrates a construction of a temperature reference voltage generation circuit according to an embodiment of the present disclosure.

FIG. 5 illustrates a construction of a reference voltage generation circuit according to an embodiment of the present disclosure.

FIG. 6 illustrates a circuit diagram of a high-temperature trimming circuit according to an embodiment of the present disclosure.

FIG. 7 illustrates a construction of a voltage selection unit according to an embodiment of the present disclosure.

FIG. 8 illustrates a circuit diagram of a bulk voltage generation circuit according to an embodiment of the present disclosure.

FIG. 9 illustrates a circuit diagram of an internal circuit according to an embodiment of the present disclosure.

FIG. 10 is a graph illustrating a change in bulk voltage versus temperature according to an embodiment of the present disclosure.

FIG. 11 illustrates a construction of a memory device according to an embodiment of the present disclosure.

FIG. 12 illustrates a construction of a first core die according to an embodiment of the present disclosure.

FIG. 13 illustrates a construction of a first temperature reference voltage generation circuit according to an embodiment of the present disclosure.

FIG. 14 illustrates a construction of a first reference voltage generation circuit according to an embodiment of the present disclosure.

FIG. 15 illustrates a construction of a first voltage selection unit according to an embodiment of the present disclosure.

FIG. 16 illustrates a construction of a first bulk voltage generation circuit according to an embodiment of the present disclosure.

FIG. 17 illustrates a construction of a second core die according to an embodiment of the present disclosure.

FIG. 18 illustrates a construction of a second temperature reference voltage generation circuit according to an embodiment of the present disclosure.

FIG. 19 illustrates a construction of a second reference voltage generation circuit according to an embodiment of the present disclosure.

FIG. 20 illustrates a construction of a second voltage selection unit according to an embodiment of the present disclosure.

FIG. 21 illustrates a construction of a second bulk voltage generation circuit according to an embodiment of the present disclosure.

FIG. 22 is a graph illustrating a change in the bulk voltage versus temperature according to an embodiment of the present disclosure.

### DETAILED DESCRIPTION

The cross-hatching throughout the figures illustrates corresponding or similar areas between the figures rather than indicating the materials associated with the areas.

Terms such as “first” and “second” are used to distinguish between various components and do not imply size, order, priority, quantity, or importance of the components. For example, a first component may be referred to as a second component in one example, and the second element may be referred to as a first element in another example.

When one component is identified as “connected” to another component, the components may be connected directly or through at least one intervening component between the components. When two components are identified as “directly connected,” one component is directly connected to the other component without an intervening component between the two components.

Terms such as “vertical,” “over,” “on,” “upper,” “lower,” “upward,” “higher,” “high,” “low,” “left,” “right,” “column,” “level,” and other terms implying relative spatial relationship or orientation are utilized only for the purpose of ease of description or reference to a drawing and are not otherwise limiting.

A “logic high level” and a “logic low level” are used to describe the logic levels of signals. A signal having a logic high level is distinguished from a signal having a logic low level. For example, when a signal having a first voltage corresponds to a signal having a logic high level, a signal having a second voltage may correspond to a signal having a logic low level. According to an embodiment, a logic high level may be set to a voltage higher than a logic low level. According to an embodiment, the logic levels of signals may be set to different logic levels or opposite logic levels. For example, a signal having a logic high level may be set to have a logic low level in some embodiments, and a signal having a logic low level may be set to have a logic high level in some embodiments.

A “binary bit set” includes a combination of logic levels of bits included in a signal. When a logic level of each of the bits included in the signal is changed, a binary bit set of the signal is different. For example, when the logic level of each of two bits included in a signal is logic low level, logic low level when the two bits are included in the signal, a binary bit set of the signal is 00. When the logic level of each of the two bits included in the signal is logic low level, logic high level, a binary bit set of the signal is 01.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

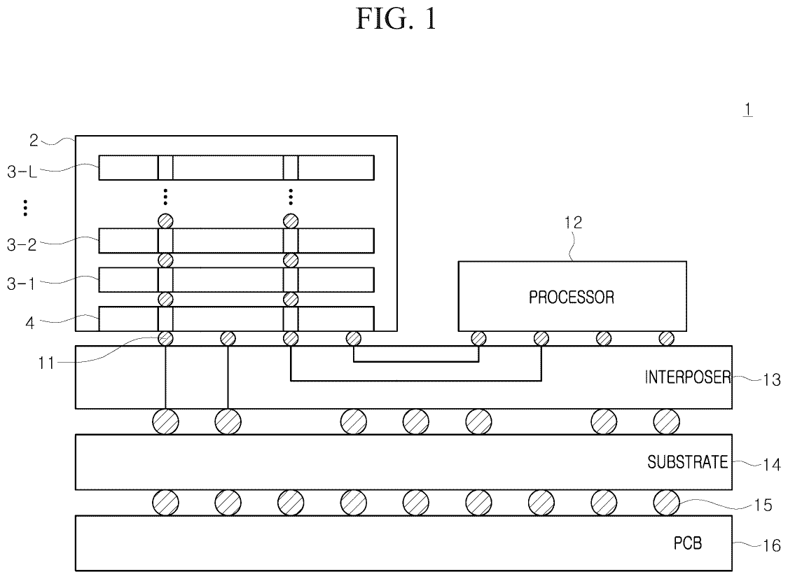

FIG. 1 illustrates a configuration of a stack memory system 1 according to an embodiment of the present disclosure.

As illustrated in FIG. 1, the stack memory system 1 includes a memory device 2 over an interposer 13 with micro bump pads 11 in between. The memory device 2 stores data received from a processor 12 or outputs data stored in the memory device 2 to the processor 12 under control of the processor 12. The memory device 2 includes a base die 4 and a plurality of core dies 3-1 to 3-L. The plurality of core dies 3-1 to 3-L are stacked over the base die 4 using the micro bump pads 11.

The base die 4 and the plurality of core dies 3-1 to 3-L are vertically connected using through silicon vias (TSVs). The base die 4 controls data transmitted between the processor 12 and the core dies 3-1 to 3-L. The base die 4 receives a source voltage VDD as an operating voltage that is utilized during operations of internal circuits included in the base die 4. The base die 4 receives the source voltage VDD from a printed circuit board PCB 16 through a substrate 14 and the interposer 13. The plurality of core dies 3-1 to 3-L use a peri-voltage VPERI as an operating voltage during internal operations of internal circuits included in the plurality of core dies 3-1 to 3-L. The plurality of core dies 3-1 to 3-L generate the peri-voltage VPERI from the source voltage VDD that is received through the base die 4. The plurality of core dies 3-1 to 3-L each generate the peri-voltage VPERI at a lower voltage level than the source voltage VDD and use the peri-voltage VPERI as an operating voltage. The internal operations of the internal circuit includes a read operation and a write operation performed by electrically driving the internal circuit. For example, the internal operations include a read operation and a write operation performed by electrically driving a column decoder included in the internal circuit. The present disclosure is not limited to internal operations including a read operation and a write operation through the internal circuit and may also include operation of a circuit including a metal oxide semiconductor (MOS) transistor that operates based on the peri-voltage.

The plurality of core dies 3-1 to 3-L may have different process, voltage, temperature (PVT) conditions. PVT information refers to information regarding a process, a voltage, and a temperature within an electronic device, such as the plurality of core dies 3-1 to 3-L.

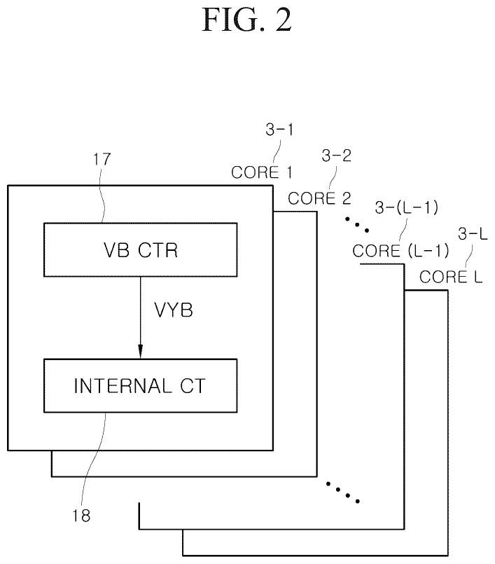

FIG. 2 illustrates a configuration of the plurality of core dies 3-1 to 3-L according to an embodiment of the present disclosure.

As illustrated in FIG. 2, the plurality of core dies 3-1 to 3-L each includes a bulk voltage control circuit VB CTR 17 and an internal circuit INTERNAL CT 18. The bulk voltage control circuit 17 generates a bulk voltage VYB and outputs the bulk voltage VYB to the internal circuit 18 that is electrically connected to the bulk voltage control circuit 17. The bulk voltage VYB is an internal voltage and includes a back bias voltage that is applied to a body of a MOS transistor. The plurality of core dies 3-1 to 3-L may have different PVT conditions. As a result, the plurality of core dies 3-1 to 3-L may each generate the bulk voltage VYB at a different voltage level.

For example, when a MOS transistor that receives the bulk voltage from each of the plurality of core dies 3-1 to 3-L is a PMOS transistor, the bulk voltage VYB, an internal voltage, has a lower voltage level in a low-temperature or cold condition, for which an internal temperature is identified for adjustment, and has a higher voltage level in a high-temperature or hot condition, for which an internal temperature is identified for adjustment. For example, when an internal temperature corresponds to a high-temperature condition identified for adjustment, increase in the leakage current of the internal circuit 18 causes deterioration, which deterioration also occurs during performance of a fast operation, in a process condition, due to increase in leakage current of the internal circuit 18. Accordingly, when the leakage current increases or the fast operation is performed, the bulk voltage control circuit 17 generates the bulk voltage VYB at a higher voltage level. For example, when an internal temperature corresponds to a low-temperature condition identified for adjustment, increase in CAS to CAS delay tCCD causes deterioration, which deterioration also occurs when a slow operation, a process condition, is performed due to tCCD increase. Accordingly, when the tCCD increases or the slow operation is performed, the bulk voltage control circuit 17 generates the bulk voltage VYB at a lower voltage level.

When the MOS transistor that receives the bulk voltage from each of the plurality of core dies 3-1 to 3-L is an NMOS transistor, the bulk voltage VYB, an internal voltage, is adjusted to a voltage level lower than a voltage level obtained under a nominal-temperature condition in a high-temperature condition, for which an internal temperature is identified for adjustment, and is adjusted to a voltage level higher than a voltage level obtained under the nominal temperature condition in a low-temperature condition, for which an internal temperature is identified for adjustment. For example, when an internal temperature corresponds to a high-temperature condition for which internal temperature is identified for adjustment, while a fast operation is performed, the bulk voltage control circuit 17 generates the bulk voltage VYB at a lower voltage level. For example, when an internal temperature corresponds to a low-temperature condition for which internal temperature is identified for adjustment, while a slow operation is performed, the bulk voltage control circuit 17 generates the bulk voltage VYB at a higher voltage level.

As described, in an embodiment of the present disclosure, the direction of a change in the bulk voltage attributable to a PVT condition depends on whether a transistor that receives the bulk voltage through the body of the transistor is a PMOS transistor or an NMOS transistor.

The internal circuit 18 includes at least one MOS transistor that operates based on the bulk voltage VYB. For example, the internal circuit 18 includes a column decoder YDEC having a PMOS transistor or an NMOS transistor that receives the bulk voltage VYB through the body of the PMOS transistor or the NMOS transistor.

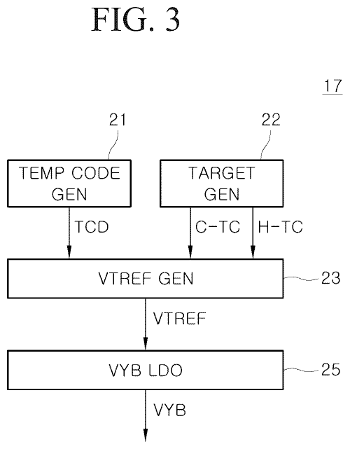

FIG. 3 illustrates a configuration of the bulk voltage control circuit 17 according to an embodiment of the present disclosure.

As illustrated in FIG. 3, the bulk voltage control circuit 17 may include a temperature code generation circuit TEMP CODE GEN 21, a target code generation circuit TARGET GEN 22, a temperature reference voltage generation circuit VTREF GEN 23, and a bulk voltage generation circuit VYB LDO 25.

The temperature code generation circuit 21 generates a temperature code TCD as a binary bit set corresponding to an internal temperature. For example, the temperature code generation circuit 21 measures an internal temperature and generates the temperature code TCD corresponding to the binary bit set based on the internal temperature.

The target code generation circuit 22 generates a high-temperature code H-TC and a low-temperature code C-TC that are each a binary bit set. For example, the target code generation circuit 22 calculates or determines a target voltage level for the bulk voltage in the low-temperature condition or high-temperature condition for which an internal temperature is identified for adjustment, based on a speed characteristic (fast or slow) and a leakage current characteristic of a process condition of each of the plurality of core dies. The target code generation circuit 22 generates the high-temperature code H-TC or the low-temperature code C-TC as a binary bit set to trim the bulk voltage based on the target voltage level of the bulk voltage. In this example, the high-temperature code H-TC or the low-temperature code C-TC are generated as a code into which the speed characteristic (fast or slow) and the leakage current characteristic of the process condition of each of the plurality of core dies are incorporated by using, as information, a value obtained by performing a cut operation on an e-fuse or a fuse array that is commonly used in DRAM. The value obtained by performing the cut operation on the fuse array is transferred to a latch during a boot-up operation and used to generate the high-temperature code H-TC and the low-temperature code C-TC.

The temperature reference voltage generation circuit 23 outputs, to the bulk voltage generation circuit 25, a temperature reference voltage VTREF that is trimmed based on the high-temperature code H-TC, the low-temperature code C-TC, and the temperature code TCD.

The bulk voltage generation circuit 25 generates the bulk voltage VYB based on the temperature reference voltage VTREF. The bulk voltage generation circuit 25 has the structure of an internal voltage generation circuit LDO that generates the bulk voltage VYB by using the temperature reference voltage VTREF as a reference voltage.

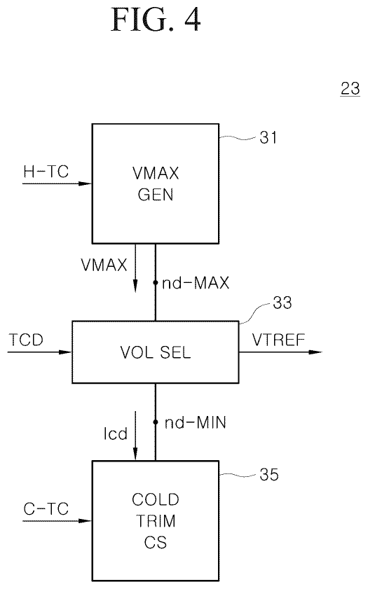

FIG. 4 illustrates a configuration of the temperature reference voltage generation circuit 23 according to an embodiment of the present disclosure. The terms “maximum” or “MAX” and “minimum” or “MIN” as used in the present disclosure are labels utilized for identification purposes only and do not necessarily indicate that a maximum value or minimum value is associated with the labelled item. For example, a maximum voltage may be referred to as an upper voltage or a first voltage, a minimum voltage may be referred to as a lower voltage or a second voltage, a maximum node nd-MAX may be referred to as a first node, and a minimum node nd-MIN may be referred to as a second node.

As illustrated in FIG. 4, the temperature reference voltage generation circuit 23 includes a maximum reference voltage generation circuit VMAX GEN 31, a voltage selection unit VOL SEL 33, and a low-temperature trimming current source COLD TRIM CS 35. The maximum reference voltage generation circuit 31 generates a maximum voltage VMAX, upper voltage, or first voltage based on the high-temperature code H-TC.

The voltage selection unit 33 includes a voltage divider that includes several resistors between a maximum node nd-MAX, or first node, at the the maximum voltage VMAX and a minimum node nd-MIN, or second node, at a minimum voltage VMIN, or second voltage. The voltage selection unit 33 divides voltage between the maximum voltage VMAX and the minimum voltage VMIN and includes a multiplexer MUX that outputs one of a plurality of internal division voltages VDIV-1 to VDIV-L) based on the temperature code TCD. The voltage selection unit 33 generates the plurality of internal division voltages VDIV-1 to VDIV-L by dividing voltage between the maximum voltage VMAX or first voltage and a minimum voltage VMIN or second voltage and selects one of the plurality of internal division voltages VDIV-1 to VDIV-L as the temperature reference voltage VTREF based on the temperature code TCD.

The low-temperature trimming current source 35 is connected between the minimum node nd-MIN or second node and a ground node and generates a temperature-variable current Icd, the magnitude of which is adjusted based on the low-temperature code C-TC. The temperature-variable current Icd generated by the low-temperature trimming current source 35 flows from the minimum node nd-MIN toward the ground node. Accordingly, the low-temperature trimming current source 35 adjusts the voltage level of the minimum node nd-MIN by changing the amount of charge at the minimum node nd-MIN. For example, when a MOS transistor that receives the bulk voltage is a PMOS transistor, when the low-temperature trimming current source 35 increases the amount of current of the temperature-variable current Icd based on the low-temperature code, because an internal temperature does not correspond to the high-temperature condition for which an internal temperature is identified for adjustment, the maximum voltage VMAX is constant, and the internal temperature corresponds to the low-temperature condition for which an internal temperature is identified for adjustment, the amount of charge discharged from the maximum node nd-MAX of the voltage selection unit 33, at the voltage level of the maximum voltage VMAX, toward the ground node increases. Accordingly, a potential difference between the maximum node nd-MAX and the minimum node nd-MIN increases compared to the previous potential difference. A difference between the voltage levels of the plurality of internal division voltages VDIV-1 to VDIV-L) is divided based on the increased potential difference is increased compared to the previous difference.

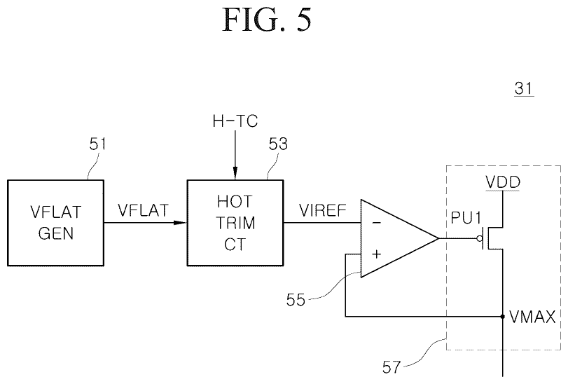

FIG. 5 illustrates a configuration of the maximum reference voltage generation circuit 31 according to an embodiment of the present disclosure.

As illustrated in FIG. 5, the maximum reference voltage generation circuit 31 includes a flat reference voltage generation circuit VFLAT GEN 51, a high-temperature trimming circuit HOT TRIM CT 53, a first comparator 55, and an internal voltage driving circuit 57.

The flat reference voltage generation circuit 51 generates a flat reference voltage VFLAT at a constant voltage level based on a source voltage VDD. The high-temperature trimming circuit 53 receives the flat reference voltage VFLAT and outputs an internal reference voltage VIREF by trimming the flat reference voltage VFLAT based on the high-temperature code H-TC. The first comparator 55 generates a first pull-up signal PU1 by comparing the internal reference voltage VIREF and the maximum reference voltage VMAX. For example, the first comparator 55 receives the internal reference voltage VIREF at a negative input terminal of an OP amp, receives the maximum voltage VMAX at a positive input terminal of the OP amp and generates the first pull-up signal PU1 by performing a comparison operation on the internal reference voltage VIREF and the maximum voltage VMAX. The internal voltage driving circuit 57 drives the maximum reference voltage VMAX to the voltage level of the source voltage VDD when the first pull-up signal PU1 is activated. For example, the internal voltage driving circuit 57 includes a PMOS transistor that receives the first pull-up signal PU1 at a gate terminal and drives the maximum voltage VMAX to the voltage level of the source voltage VDD when a channel is formed based on the first pull-up signal PU1 at the gate.

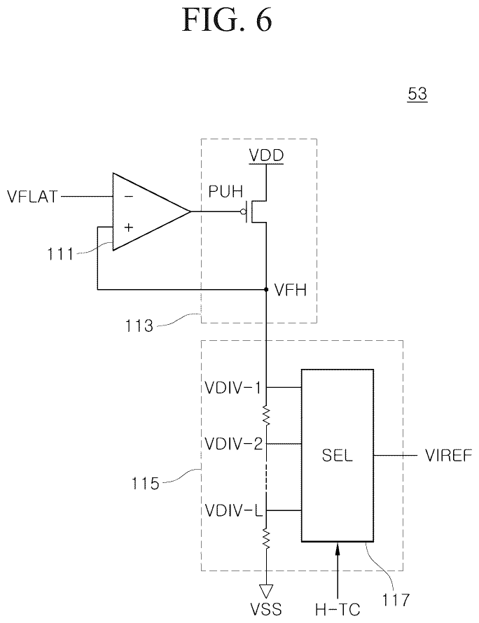

FIG. 6 illustrates a circuit diagram of the high-temperature trimming circuit 53 according to an embodiment of the present disclosure.

As illustrated in FIG. 6, the high-temperature trimming circuit 53 includes a high-temperature comparator 111, a high-temperature voltage driving circuit 113, a high-temperature internal voltage divider 115, and a high-temperature voltage selector SEL 117.

The high-temperature comparator 111 generates a high-temperature pull-up signal PUH by comparing the flat reference voltage VFLAT and a high-temperature feedback voltage VFH. For example, the high-temperature comparator 111 receives the flat reference voltage VFLAT at a negative input terminal of an OP amp, receives the high-temperature feedback voltage VFH at a positive input terminal of the OP amp, and generates the high-temperature pull-up signal PUH by performing a comparison operation on the flat reference voltage VFLAT and the high-temperature feedback voltage VFH. When the high-temperature pull-up signal PUH is activated at logic high level, the high-temperature voltage driving circuit 113 drives the high-temperature feedback voltage VFH to the voltage level of the source voltage VDD. For example, the high-temperature voltage driving circuit 113 includes a PMOS transistor that receives the high-temperature pull-up signal PUH at a gate terminal and drives the high-temperature feedback voltage VFH to the voltage level of the source voltage VDD when a channel is formed based on the high-temperature pull-up signal PUH at the gate. The high-temperature internal voltage divider 115 generates a plurality of high-temperature division voltages by dividing the high-temperature feedback voltage VFH. The high-temperature voltage selector 117 outputs one of the plurality of high-temperature division voltages as the internal reference voltage VIREF based on the high-temperature code H-TC. For example, the high-temperature internal voltage divider 115 includes a voltage divider that generates the plurality of high-temperature division voltages by dividing a voltage, high-temperature feedback voltage VFH, by using a plurality of resistors and a multiplexer MUX that selects one of the plurality of high-temperature division voltages based on the high-temperature code H-TC and outputs the selected high-temperature division voltage.

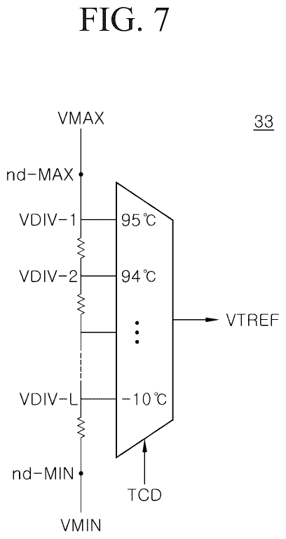

FIG. 7 illustrates a configuration of the voltage selection unit 33 according to an embodiment of the present disclosure.

As illustrated in FIG. 7, the voltage selection unit 33 generates the plurality of internal division voltages VDIV-1 to VDIV-L by dividing voltage between the maximum voltage VMAX or first voltage and the minimum voltage VMIN or second voltage and outputs one of the plurality of internal division voltages VDIV-1 to VDIV-L as the temperature reference voltage VTREF based on the temperature code TCD. For example, the voltage selection unit 33 includes a voltage divider that includes several resistors from a maximum node nd-MAX at the voltage level of the maximum voltage VMAX to the minimum node nd-MIN at the voltage level of the minimum voltage VMIN and that divides the voltage between VMAX and VMIN and a multiplexer MUX that receives the plurality of internal division voltages VDIV-1 to VDIV-L, uses the temperature code TCD as a selection signal, and outputs one of the plurality of internal division voltages VDIV1 to VDIV-L as the temperature reference voltage VTREF.

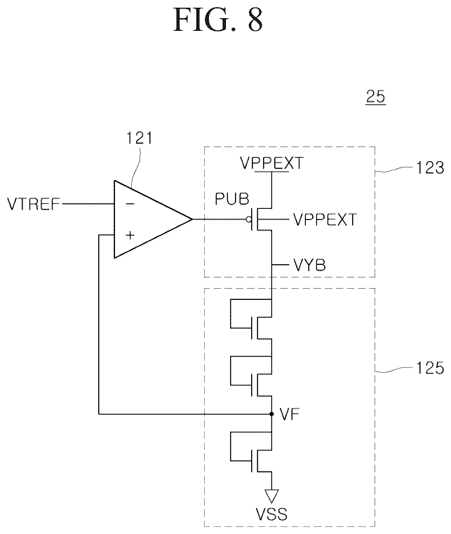

FIG. 8 illustrates a circuit diagram of the bulk voltage generation circuit 25 according to an embodiment of the present disclosure.

As illustrated in FIG. 8, the bulk voltage generation circuit 25 includes a bulk voltage comparator 121, a bulk voltage driving circuit 123, and a feedback voltage generation circuit 125. The bulk voltage comparator 121 generates a bulk pull-up signal PUB by comparing the temperature reference voltage VTREF and a feedback voltage VF. The bulk voltage driving circuit 123 drives the bulk voltage VYB to the voltage level of an external voltage VPPEXT when the bulk pull-up signal PUB is activated at a logic low level and outputs the bulk voltage VYB. The feedback voltage generation circuit 125 generates the feedback voltage VF that varies based on the bulk voltage VYB. For example, the feedback voltage generation circuit 125 has a configuration such as the configuration of a voltage divider in which a plurality of diode-connected NMOS transistors, each having a gate connected to a drain, is disposed between a node at the voltage level of the bulk voltage VYB and a ground voltage VSS. The feedback voltage generation circuit 125 generates the feedback voltage VF at a node that is coupled to a positive input terminal of the bulk voltage comparator 121, where the feedback voltage VF is generated at a predetermined voltage level. For example, when two diode-connected transistors are connected between a node at the maximum voltage and the node at the feedback voltage VF, and one diode-connected transistor is connected between the node at the feedback voltage VF and the ground voltage, the voltage level of the bulk voltage VYB that is output on the node at the maximum voltage is three times the voltage level of the feedback voltage VF.

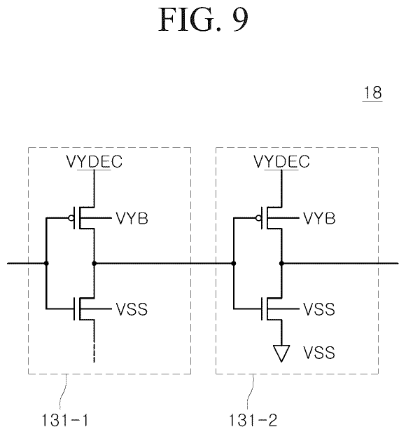

FIG. 9 illustrates a circuit diagram of the internal circuit 18 according to an embodiment of the present disclosure.

As illustrated in FIG. 9, the internal circuit 18 includes a plurality of column decoders YDEC 131-1 to 131-2. Each of the plurality of column decoders 131-1 to 131-2 includes at least one MOS transistor that receives a driving voltage VYDEC and the bulk voltage VYB, a separate voltage, through the body of the MOS transistor. For example, the column decoder includes a PMOS or NMOS transistor and performs a pull-up operation. In this example, the bulk voltage VYB is applied to the body of the PMOS transistor as a back bias voltage and can prevent leakage current or deterioration of tCCD by compensating for change in the threshold voltage according to a PVT condition.

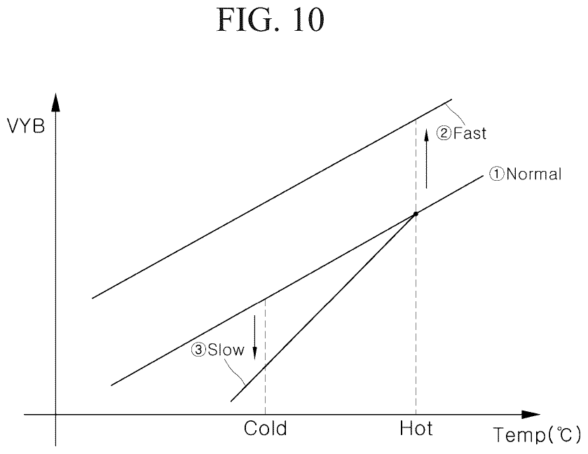

FIG. 10 is a graph illustrating change in the bulk voltage VYB according to a PVT condition such as temperature when a MOS transistor that receives the bulk voltage VYB through the body of the MOS transistor is a PMOS transistor according to an embodiment of the present disclosure.

As illustrated in FIG. 10, the graph includes an X axis representing temperature and a Y axis representing the bulk voltage VYB. In the example when a change in the bulk voltage VYB, an internal voltage, compensates for the threshold voltage of a PMOS transistor, the bulk voltage VYB has a lower voltage level in the low-temperature condition and a higher voltage level in the high-temperature condition.

The \textcircled{1} Normal curve, depicted as a straight line, is a curve of a common example that does not correspond to either the low-temperature condition or the high-temperature condition for which an internal temperature is identified for adjustment and shows the bulk voltage VYB at a higher voltage level as the internal temperature increases.

The \textcircled{2} Fast, or hot, curve of the bulk voltage VYB, depicted as a straight line, is a curve for a process condition when a fast operation is performed. Adjustment of the bulk voltage VYB compensates for PVT conditions such as the high-temperature condition. A Fast process condition when a fast operation is performed is characterized as a high-temperature condition for which an internal temperature is identified for adjustment. For example, the condition when the leakage current of the internal circuit 18 is increased and the condition when a fast operation is performed are characterized as high-temperature conditions for which an internal temperature is identified for adjustment. When the PVT condition corresponds to the high-temperature condition for which an internal temperature is identified for adjustment, deterioration in which increased leakage current of the internal circuit 18 occurs and deterioration in which increased leakage current of the internal circuit 18 occurs in the process condition when a fast operation is performed. Accordingly, the bulk voltage VYB having a higher voltage level may result when the leakage current is increased or the fast operation is performed.

The \textcircled{3} Slow, or cold curve of the bulk voltage VYB, depicted as a straight line, is a curve for a slow process condition when a slow operation is performed. Adjustment of the bulk voltage VYB compensates for PVT conditions such as the low-temperature condition. The slow process condition when a slow operation is performed is characterized as a low-temperature condition for which an internal temperature is identified for adjustment. For example, the condition when tCCD is increased and the condition when a slow operation is performed are characterized as low-temperature conditions for which an internal temperature is identified for adjustment. When the PVT condition corresponds to the low-temperature condition for which an internal temperature is identified for adjustment, deterioration in which increased tCCD occurs and deterioration in which increased tCCD occurs in the process condition when a slow operation is performed. Accordingly, the bulk voltage VYB having a lower voltage level may result when the tCCD is increased or the slow operation is performed.

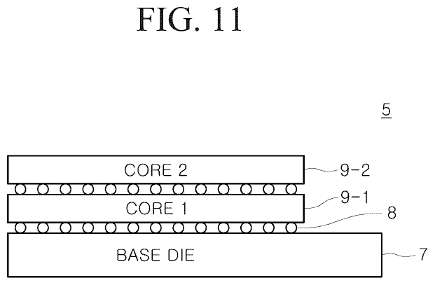

FIG. 11 illustrates a configuration of a memory device 5 according to an embodiment of the present disclosure.

As illustrated in FIG. 11, the memory device 5 includes a base die 7, a first core die CORE 1 9-1, and a second core die CORE 2 9-2. The memory device 5 may be formed over an interposer (not illustrated) and a processor (not illustrated) with micro bump pads 8 in between.

The first core die 9-1 and the second core die 9-2 may have different PVT conditions. PVT information refers to information regarding a process, a voltage, and a temperature within an electronic device, such as the first core die 9-1 and the second core die 9-2. The first core die 9-1 and the second core die 9-2 generate a first bulk voltage VYB1 and a second bulk voltage VYB2, respectively, based on a first process condition and a second process condition, respectively, where the first process condition is a different PVT condition from the second process condition.

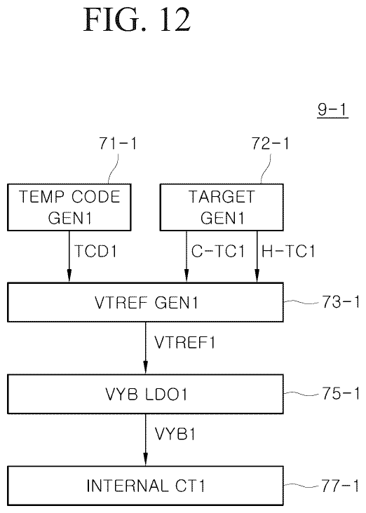

The first process condition is a process condition when a fast operation is performed. For example, deterioration in which increased leakage current occurs when the first process condition corresponds to the high-temperature condition for which an internal temperature is identified for adjustment. Deterioration in which increased leakage current occurs when a fast operation is performed corresponds to the high-temperature condition for which an internal temperature is identified for adjustment. When the leakage current is deteriorated and the condition in which a fast operation is performed are characterized as high-temperature conditions for which an internal temperature is identified for adjustment. Accordingly, when the leakage current is deteriorated or the fast operation is performed, the first core die 9-1 generates the first bulk voltage VYB1 at a higher voltage level. The first core die 9-1 is stacked over the base die 7 and generates the first bulk voltage VYB1, the voltage level of which is changed based on the first process condition, and supplies the first bulk voltage VYB1 to the body of at least one first MOS transistor included in a first internal circuit INTERNAL CT1 77-1 of the first core die 9-1 of FIG. 12.

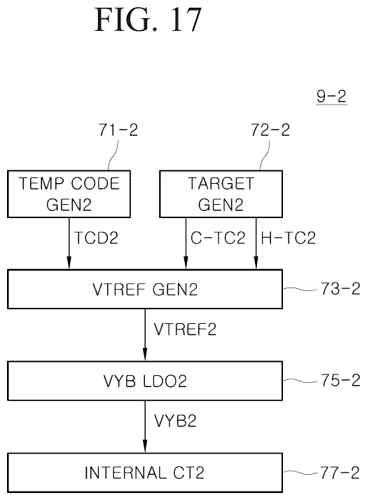

The second process condition is a process condition when a slow operation is performed. When the second process condition corresponds to the low-temperature condition for which an internal temperature is identified for adjustment, deterioration occurs due to increased tCCD. Deterioration in which increased tCCD occurs when a slow operation is performed corresponds to the low-temperature condition for which an internal temperature is identified for adjustment. When tCCD is deteriorated and the condition in which a slow operation is performed are characterized as low-temperature conditions for which an internal temperature is identified for adjustment. Accordingly, when tCCD is deteriorated or the slow operation is performed, the second core die 9-2 generates the second bulk voltage VYB2 at a lower voltage level. The second core die 9-2 is stacked over the first core die 9-1 and generates the second bulk voltage VYB2, the voltage level of which is changed based on the second process condition, and supplies the second bulk voltage VYB2 to the body of at least one second MOS transistor included in a second internal circuit INTERNAL CT2 77-2 of the second core die 9-2 of FIG. 17.

FIG. 12 illustrates a configuration of the first core die 9-1 according to an embodiment of the present disclosure.

As illustrated in FIG. 12, the first core die 9-1 includes a first temperature code generation circuit TEMP CODE GEN1 71-1, a first target code generation circuit TARGET GEN2 72-1, a first temperature reference voltage generation circuit VTREF GEN1 73-1, a first bulk voltage generation circuit VYB LDO1 75-1, and the first internal circuit 77-1.

The first temperature code generation circuit 71-1 generates a first common temperature code TCD1 as a binary bit set corresponding to an internal temperature. For example, the first temperature code generation circuit 71-1 measures the internal temperature and generates the first common temperature code TCD1 corresponding to the binary bit set based on the measured internal temperature.

The first target code generation circuit 72-1 generates a first high-temperature code H-TC1 and a first low-temperature code C-TC1 that are each a binary bit set. For example, the first target code generation circuit 72-1 calculates or determines a target voltage level for a bulk voltage in the low-temperature condition or the high-temperature condition for which an internal temperature is identified for adjustment based on a speed characteristic (fast or slow) and a leakage current characteristic of the process condition of each of a plurality of core dies. The first target code generation circuit 72-1 generates the first high-temperature code H-TC1 or the first low-temperature code C-TC1 as a binary bit set to trim the bulk voltage based on the target voltage level of the bulk voltage. In this example, the first high-temperature code H-TC1 or the first low-temperature code C-TC1 are generated as a code into which the speed characteristic (fast or slow) and the leakage current characteristic of the process condition of each of the plurality of core dies are incorporated by using, as information, a value obtained by performing a cut operation on an e-fuse or a fuse array that is commonly used in DRAM. The value obtained by performing the cut operation on the fuse array is transferred to a latch during a boot-up operation and used to generate the high-temperature code H-TC and the low-temperature code C-TC.

For example, when the first process condition is a condition in which a fast operation is performed, when a MOS transistor that receives the bulk voltage through the body of the MOS transistor is a PMOS transistor, the first target code generation circuit 72-1 activates the first high-temperature code H-TC1 and deactivates the first low-temperature code C-TC1. The first temperature reference voltage generation circuit 73-1 generates a first temperature reference voltage VTREF1, the voltage level of which is adjusted according to the first high-temperature code H-TC1 activated by the first target code generation circuit 72-1 and the first common temperature code TCD1. The first bulk voltage generation circuit 75-1 generates the first bulk voltage VYB1, the voltage level of which is adjusted based on the first temperature reference voltage VTREF1. At least one first MOS transistor included in the first internal circuit INTERNAL CT1 77-1 receives the first bulk voltage VYB1 via the body of the first MOS transistor.

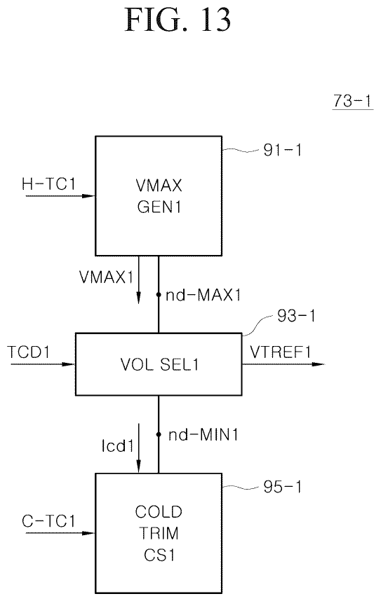

FIG. 13 illustrates a configuration of the first temperature reference voltage generation circuit 73-1 according to an embodiment of the present disclosure.

As illustrated in FIG. 13, the first temperature reference voltage generation circuit 73-1 includes a first maximum reference voltage generation circuit VMAX GEN1 91-1, a first voltage selection unit VOL SEL1 93-1, and a first low-temperature trimming current source COLD TRIM CS1 95-1. The first maximum reference voltage generation circuit 91-1 generates a first maximum reference voltage VMAX1 or upper voltage voltage, the voltage level of which is adjusted based on the first high-temperature code H-TC1. The first voltage selection unit 93-1 generates a plurality of first internal division voltages VDIV-11 to VDIV-1L each having a voltage level determined by dividing a voltage between the first maximum reference voltage VMAX1 and the voltage at a first minimum node nd-MIN1 and selects one of the plurality of first internal division voltages VDIV-11 to VDIV-1L as a first temperature reference voltage VTREF1 based on the first common temperature code TCD1. The first low-temperature trimming current source 95-1 is connected between a first minimum node nd-MIN 1 and a ground voltage and generates a first temperature-variable current Icd1. In this example, when a MOS transistor that receives the bulk voltage through the body of the MOS transistor is a PMOS transistor, the first core die 9-1 having a first process condition does not generate a first temperature-variable current because the first low-temperature code C-TC1 is deactivated.

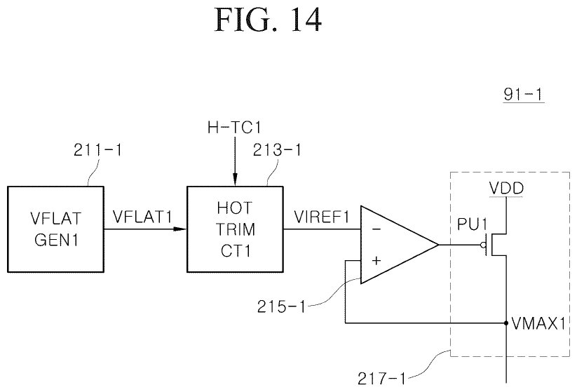

FIG. 14 illustrates a configuration of the first maximum reference voltage generation circuit 91-1 according to an embodiment of the present disclosure.

As illustrated in FIG. 14, the first maximum reference voltage generation circuit 91-1 includes a first flat reference voltage generation circuit VFLAT GEN1 211-1, a first high-temperature trimming circuit HOT TRIM CT1 213-1, a first comparator 215-1, and a first internal voltage driving circuit 217-1. The first flat reference voltage generation circuit 211-1 generates a first flat reference voltage VFLAT1 at a constant voltage level based on a source voltage VDD. The first high-temperature trimming circuit 213-1 receives the first flat reference voltage VFLAT1 and outputs a first internal reference voltage VIREF1 by adjusting the voltage level of the first flat reference voltage VFLAT1 based on the first high-temperature code H-TC1. The first comparator 251-1 generates a first pull-up signal PU1 by comparing the first internal reference voltage VIREF1 and the first maximum reference voltage VMAX1. The first internal voltage driving circuit 217-1 drives the first maximum reference voltage VMAX1 to the voltage level of the source voltage VDD when the first pull-up signal PU1 is activated at a logic low level.

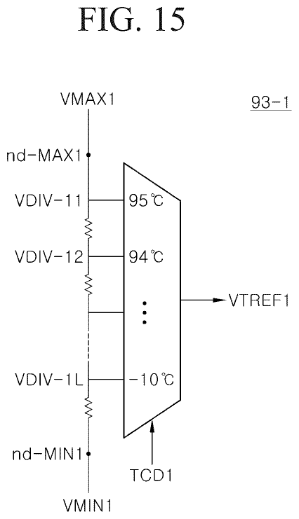

FIG. 15 illustrates a configuration of the first voltage selection unit 93-1 according to an embodiment of the present disclosure.

As illustrated in FIG. 15, the first voltage selection unit 93-1 generates the plurality of first internal division voltages VDIV-11 to VDIV-1L by dividing voltage between the first maximum voltage VMAX1 or upper voltage and a first minimum voltage VMIN1 or lower voltage and selects one of the plurality of first internal division voltages VDIV-11 to VDIV-1L as the first temperature reference voltage VTREF1 based on the first common temperature code TCD1. For example, the first voltage selection unit 93-1 includes a voltage divider that includes several resistors between a maximum node nd-MAX at the voltage level of the first maximum voltage VMAX1 and the first minimum node nd-MIN1 at the voltage level of the first minimum voltage VMIN1 and that divides the voltage between the first maximum voltage VMAX1 and the first minimum voltage VMIN1 and a multiplexer MUX that outputs one of the plurality of first internal division voltages VDIV-11 to VDIV-1L as the first temperature reference voltage VTREF1 based on the first common temperature code TCD1.

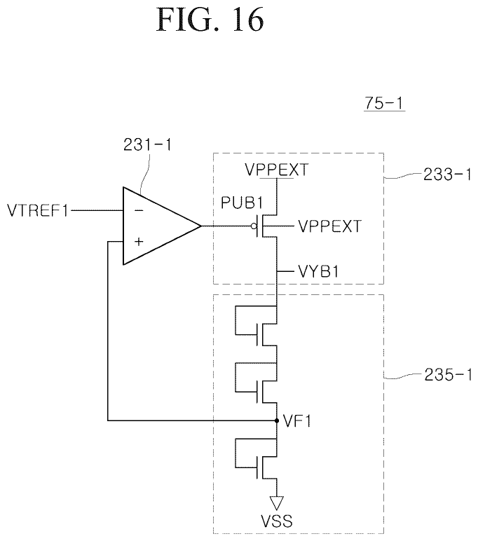

FIG. 16 illustrates a configuration of the first bulk voltage generation circuit 75-1 according to an embodiment of the present disclosure.

As illustrated in FIG. 16, the first bulk voltage generation circuit 75-1 includes a first bulk voltage comparator 231-1, a first bulk voltage driving circuit 233-1, and a first feedback voltage generation circuit 235-1. The first bulk voltage comparator 231-1 generates a first bulk pull-up signal PUB1 by comparing the first temperature reference voltage VTREF1 and a first feedback voltage VF1. The first bulk voltage driving circuit 233-1 drives the first bulk voltage VYB1 to the voltage level of an external voltage VPPEXT when the first bulk pull-up signal PUB1 is activated at a logic low level and outputs the first bulk voltage VYB1. The first feedback voltage generation circuit 235-1 generates the first feedback voltage VF1 that varies based on the first bulk voltage VYB1. For example, the first feedback voltage generation circuit 235-1 has a configuration, such as the configuration of a voltage divider in which a plurality of diode-connected NMOS transistors, each having a gate connected to a drain and is disposed between a node at the voltage level of the first bulk voltage VYB1 and a ground voltage VSS. The first feedback voltage generation circuit 235-1 generates the first feedback voltage VF1 at a node that is coupled to a positive input terminal of the first bulk voltage comparator 231-1, and the feedback voltage VF is generated at a predetermined voltage level. For example, when two diode-connected transistors are connected between a node at the maximum voltage and the node at the first feedback voltage VF1, and one diode-connected transistor is connected between the node at the first feedback voltage VF1 and the ground voltage, the first bulk voltage VYB1 that is output on the node at the maximum voltage is a voltage level that is three times the voltage level of the first feedback voltage VF1.

FIG. 17 illustrates a configuration of the second core die 9-2 according to an embodiment of the present disclosure.

As illustrated in FIG. 17, the second core die 9-2 includes a second temperature code generation circuit TEMP CODE GEN2 71-2, a second target code generation circuit TARGET GEN2 72-2, a second temperature reference voltage generation circuit VTREF GEN2 73-2, a second bulk voltage generation circuit VYB LDO2 75-2, and the second internal circuit INTERNAL CT2 77-2.

The second temperature code generation circuit 71-2 generates a second temperature code TCD2 as a binary bit set corresponding to an internal temperature. For example, the second temperature code generation circuit 71-2 measures the internal temperature and generates the second temperature code TCD2 corresponding to the binary bit set based on the measured internal temperature.

The second target code generation circuit 72-2 generates a second high-temperature code H-TC2 and a second low-temperature code C-TC2 that are each a binary bit set. For example, the second target code generation circuit 72-2 calculates or determines a target voltage level for the bulk voltage in the low-temperature condition or the high-temperature condition for which an internal temperature is identified for adjustment based on a speed characteristic (fast or slow) and a leakage current characteristic of the process condition of each of a plurality of core dies. The second target code generation circuit 72-2 generates the second high-temperature code H-TC2 or the second low-temperature code C-TC2 as a binary bit set to trim the bulk voltage based on the target voltage level of the bulk voltage. In this example, the second high-temperature code H-TC2 or the second low-temperature code C-TC2 are generated as a code into which the speed characteristic (fast or slow) and the leakage current characteristic of the process condition of each of the plurality of core dies are incorporated by using, as information, a value obtained by performing a cut operation on an e-fuse or a fuse array that is commonly used in DRAM. The value obtained by performing the cut operation on the fuse array is transferred to a latch during a boot-up operation and used to generate the high-temperature code H-TC and the low-temperature code C-TC.

For example, when the second process condition is a condition in which a fast operation is performed, when a MOS transistor that receives the bulk voltage through the body of the MOS transistor is a PMOS transistor, the second target code generation circuit 72-2 activates the second high-temperature code H-TC2 and deactivates the second low-temperature code C-TC2. The second temperature reference voltage generation circuit 73-2 generates a second temperature reference voltage VTREF2 the voltage level of which is adjusted according to the second high-temperature code H-TC2 activated by the second target code generation circuit 72-2 and a second common temperature code TCD2. The second bulk voltage generation circuit 75-2 generates a second bulk voltage VYB2, the voltage level of which is adjusted based on the second temperature reference voltage VTREF2. At least one second MOS transistor included in the second internal circuit 77-2 receives the second bulk voltage VYB2 via the body of the second MOS transistor.

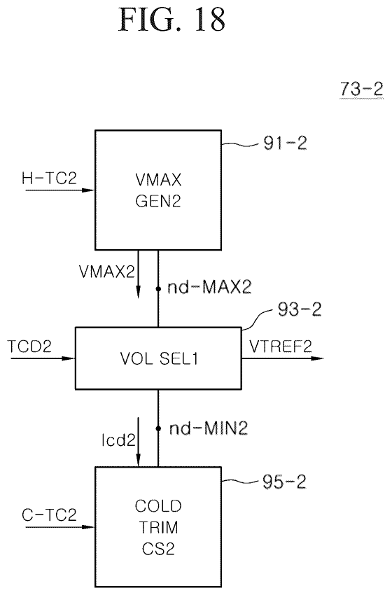

FIG. 18 illustrates a configuration of the second temperature reference voltage generation circuit 73-2 according to an embodiment of the present disclosure.

As illustrated in FIG. 18, the second temperature reference voltage generation circuit 73-2 includes a second maximum reference voltage generation circuit VMAX GEN2 91-2, a second voltage selection unit VOL SEL1 93-2, and a second low-temperature trimming current source COLD TRIM CS2 95-2. The second maximum reference voltage generation circuit 91-2 generates a second maximum reference voltage VMAX2 or upper voltage voltage. For example, when a MOS transistor that receives the bulk voltage through the body of the MOS transistor is a PMOS transistor, the second maximum reference voltage generation circuit 91-2 does not trim the second maximum reference voltage VMAX2 based on the second high-temperature code H-TC2 because the second high-temperature code H-TC2 is deactivated in the second core die 9-2 having the second process condition, a condition in which a slow operation is performed. The second voltage selection unit 93-2 generates a plurality of second internal division voltages VDIV- 21 to VDIV-2L by dividing a voltage between the second maximum reference voltage VMAX2 and the voltage at a second minimum node nd-MIN2 and selects one of the plurality of second internal division voltages VDIV-21 to VDIV-2L as a second temperature reference voltage VTREF2 based on the second temperature code TCD2. The second low-temperature trimming current source 95-2 is connected between the second minimum node nd-MIN2 and a ground voltage VSS and generates a second temperature-variable current Icd2 based on the second low-temperature code C-TC2.

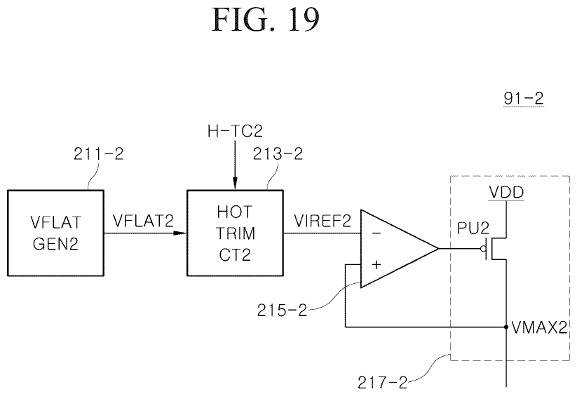

FIG. 19 illustrates a configuration of the second maximum reference voltage generation circuit 91-2 according to an embodiment of the present disclosure.

As illustrated in FIG. 19, the second maximum reference voltage generation circuit 91-2 includes a second flat reference voltage generation circuit VFLAT2 211-2, a second high-temperature trimming circuit HOT TRIM CT2 213-2, a second comparator 251-2, and a second internal voltage driving circuit 217-2. The second flat reference voltage generation circuit 211-2 generates a second flat reference voltage VFLAT2 at a constant voltage level based on a source voltage VDD. For example, when a MOS transistor that receives the bulk voltage via the body of the MOS transistor is a PMOS transistor, the second flat reference voltage generation circuit 211-2 outputs the second internal reference voltage VIREF2 without trimming the second flat reference voltage VFLAT2 because the second high-temperature code H-TC2 is deactivated when the second high-temperature trimming circuit 213-2 has the second process condition, a condition in which a slow operation is performed. The second comparator 251-2 activates a second pull-up signal PU2 by comparing the second internal reference voltage VIREF2 and the second maximum reference voltage VMAX2. When the second pull-up signal PU2 is activated at a logic low level, the second internal voltage driving circuit 217-2 drives the second maximum reference voltage VMAX2 to the voltage level of the source voltage VDD.

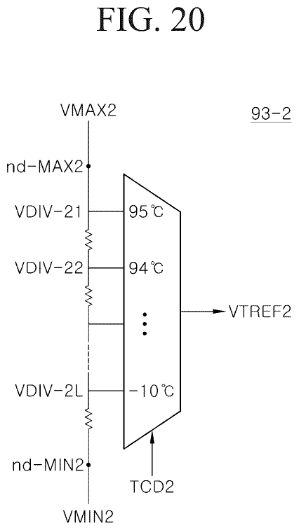

FIG. 20 illustrates a configuration of the second voltage selection unit 93-2 according to an embodiment of the present disclosure.

As illustrated in FIG. 20, the second voltage selection unit 93-2 generates the plurality of second internal division voltages VDIV-21 to VDIV-2L by dividing voltage between the second maximum voltage VMAX2 or upper voltage and a second minimum voltage VMIN2 or lower voltage and selects one of the plurality of second internal division voltages VDIV-21 to VDIV-2L) as the second temperature reference voltage VTREF2 based on the second temperature code TCD2. For example, the second voltage selection unit 93-2 includes a voltage divider that includes several resistors between a second maximum node nd-MAX2 at the voltage level of the second maximum voltage VMAX2 and the second minimum node nd-MIN2 at the voltage level of the second minimum voltage VMIN2 and that divides the voltage between the second maximum voltage VMAX2 and the second minimum voltage VMIN2 and a multiplexer (MUX) that outputs one of the plurality of second internal division voltages VDIV-21 to VDIV-2L as the second temperature reference voltage VTREF2 based on the second temperature code TCD2.

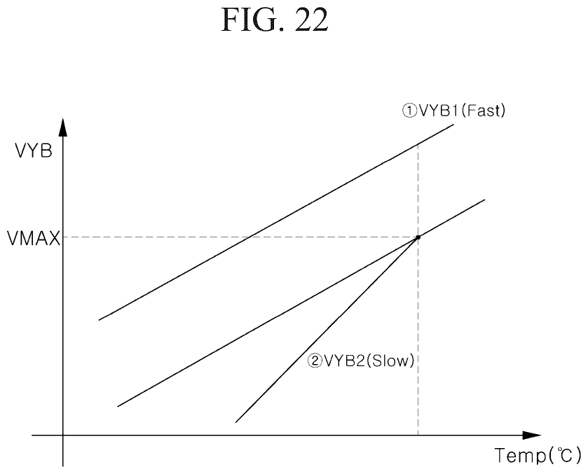

The second temperature-variable current Icd2 is generated by the second low-temperature trimming current source 95-2 that is connected between the second minimum node nd-MIN2 and the ground voltage VSS and flows in the direction of the ground voltage VSS. For example, when a MOS transistor that receives the bulk voltage via the body of the MOS transistor is a PMOS transistor, the voltage difference between consecutive second internal division voltages VDIV-21 to VDIV-2L is larger because the second temperature-variable current Icd2 increases when a slow operation is performed as in the second process condition. As a result, the second internal division voltage VDIV-21 has a higher voltage level closer to the voltage at the second maximum node nd-MAX2, and the second internal division voltage VDIV-2L has a lower voltage level closer to the second minimum node nd-MIN2. The slope of a curve increases due to an increase in the second temperature-variable current Icd2 when a change in the voltage level according to temperature follows the curve \textcircled{2}VYB2 as shown in the graph of FIG. 22.

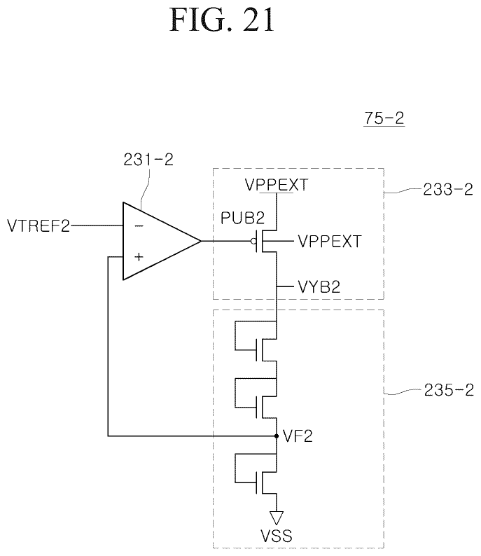

FIG. 21 illustrates a configuration of the second bulk voltage generation circuit 75-2 according to an embodiment of the present disclosure.

As illustrated in FIG. 21, the second bulk voltage generation circuit 75-2 includes a second bulk voltage comparator 231-2, a second bulk voltage driving circuit 233-2, and a second feedback voltage generation circuit 235-2. The second bulk voltage comparator 231-2 generates a second bulk pull-up signal PUB2 by comparing the second temperature reference voltage VTREF2 and a second feedback voltage VF2. The second bulk voltage driving circuit 233-2 drives the second bulk voltage VYB2 to the voltage level of an external voltage VPPEXT when the second bulk pull-up signal PUB2 is activated at a logic low level and outputs the second bulk voltage VYB2. The second feedback voltage generation circuit 235-2 generates the second feedback voltage VF2 that varies based on the second bulk voltage VYB2. For example, the second feedback voltage generation circuit 235-2 has a configuration, such as the configuration of a voltage divider in which a plurality of diode-connected NMOS transistors, each having a gate connected to a drain, is disposed between a node at the voltage level of the second bulk voltage VYB2 and the ground voltage VSS. The second feedback voltage generation circuit 235-2 generates the second feedback voltage VF2 at a node that is coupled to a positive input terminal of the second bulk voltage comparator 231-2, and the feedback voltage VF2 is generated at a predetermined voltage level. For example, when two diode-connected transistors are connected between a node at the maximum voltage and the node at the second feedback voltage VF2, and one diode-connected transistor is connected between the node at the second feedback voltage VF2 and the ground voltage VSS, the second bulk voltage VYB2 that is output on the node at the maximum voltage is a voltage level that is three times the voltage level of the second feedback voltage VF2.

FIG. 22 is a graph illustrating a change in the bulk voltage VYB according to a PVT condition such as temperature when a MOS transistor that receives the bulk voltage through the body of the MOS transistor is a PMOS transistor according to an embodiment of the present disclosure.

As illustrated in FIG. 22, the graph has an X axis representing temperature and a Y axis representing the bulk voltage VYB.

The \textcircled{1}VYB1(Fast) curve illustrates a change in the first bulk voltage VYB1 according to temperature of the first core die. At the second bulk voltage VYB2, the second low temperature trimming current source 95-2 generates the second temperature-variable current Icd2 at a level higher than a current obtained under the nominal speed operating condition, based on the second process condition, a condition at which a slow operation is performed. Accordingly, the first bulk voltage VYB1 have a higher voltage level in the temperature range of the entire region.

The \textcircled{2} (Slow) curve illustrates a change in the second bulk voltage VYB2 according to temperature of the second core die. At the second bulk voltage VYB2, the second low temperature trimming current source 95-2 generates the second temperature-variable current Icd2 at a level higher than a current level obtained under the nominal speed operating condition, based on the second process condition, a condition at which a slow operation is performed. Accordingly, the voltage level of the second bulk voltage VYB2 decreases with a greater slope as the temperature is lower from the second maximum reference voltage VMAX2.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A memory device comprising:
a base die; and
a plurality of core dies stacked over the base die, each comprising an internal circuit configured to perform an internal operation and a bulk voltage control circuit configured to generate a bulk voltage;
wherein the internal circuit comprises at least one metal oxide semiconductor (MOS) transistor configured to operate by receiving the bulk voltage that is adjusted based on an internal temperature of each of the plurality of core dies.

2. The memory device of claim 1, wherein the bulk voltage control circuit comprises:
a temperature reference voltage generation circuit configured to generate a temperature reference voltage based on a high-temperature code, a low-temperature code, and a temperature code; and
a bulk voltage generation circuit configured to drive the bulk voltage based on the temperature reference voltage and an external voltage.

3. The memory device of claim 2, wherein each of the plurality of core dies further comprises:
a target code generation circuit configured to generate the high-temperature code and the low-temperature code; and
a temperature code generation circuit configured to generate the temperature code that is a binary bit set corresponding to the internal temperature.

4. The memory device of claim 3, wherein the target code generation circuit is configured to:
generate the high-temperature code that is a binary bit set used to adjust the bulk voltage in a high-temperature condition for which the internal temperature is identified for adjustment; and
generate the low-temperature code that is a binary bit set used to adjust the bulk voltage in a low-temperature condition for which the internal temperature is identified for adjustment.

5. The memory device of claim 2, wherein the temperature reference voltage generation circuit comprises:
a first reference voltage generation circuit configured to generate a first reference voltage a voltage level of which is adjusted based on the high-temperature code;
a voltage selection unit configured to generate a plurality of internal division voltages by dividing a voltage between a first node having the first reference voltage and a second node and configured to select one of the plurality of internal division voltages as the temperature reference voltage based on the temperature code; and
a low-temperature trimming current source connected between the second node and a ground voltage and configured to generate a temperature-variable current an amount of current of which is adjusted based on the low-temperature code.

6. The memory device of claim 5, wherein the first reference voltage generation circuit comprises:
a flat reference voltage generation circuit configured to generate a flat reference voltage having a constant voltage level based on a source voltage;
a high-temperature trimming circuit configured to output the flat reference voltage as an internal reference voltage by trimming the flat reference voltage based on the high-temperature code;
a first comparator configured to generate a first pull-up signal by comparing the internal reference voltage and the first reference voltage; and
an internal voltage driving circuit configured to drive the first reference voltage to a voltage level of the source voltage when the first pull-up signal is activated.

7. The memory device of claim 6, wherein the high-temperature trimming circuit comprises:
a comparator configured to generate a pull-up signal by comparing the flat reference voltage and a feedback voltage;
a voltage driving circuit configured to drive the feedback voltage to the voltage level of the source voltage when the pull-up signal is activated;
an internal voltage divider configured to generate a plurality of division voltages by dividing the high-temperature feedback voltage; and
a voltage selector configured to output one of the plurality of division voltages as the internal reference voltage based on the high-temperature code.

8. The memory device of claim 5, wherein the low-temperature trimming current source is configured to:
generate the temperature-variable current based on the low-temperature code; and
adjust a voltage level at the second node based on the temperature-variable current.

9. The memory device of claim 2, wherein the bulk voltage generation circuit comprises:
a comparator configured to generate a bulk pull-up signal by comparing the temperature reference voltage and a feedback voltage;
a bulk voltage driving circuit configured to drive the bulk voltage to a voltage level of the external voltage when the bulk pull-up signal is activated and configured to output the bulk voltage; and
a feedback voltage generation circuit configured to generate the feedback voltage that changes based on the bulk voltage.

10. The memory device of claim 1, wherein:
the internal circuit comprises a column decoder including at least one MOS transistor; and
the MOS transistor included in the column decoder receives the bulk voltage via a body of the MOS transistor.

11. The memory device of claim 1, wherein the internal operation is a read operation or a write operation performed by electrically driving the internal circuit.

12. A memory device comprising:
a first core die stacked over a base die, configured to generate a first bulk voltage at a voltage level that varies based on a first process condition, and configured to supply the first bulk voltage to a body of at least one first metal oxide semiconductor (MOS) transistor included in a first internal circuit; and
a second core die stacked over the first core die, configured to generate a second bulk voltage at a voltage level that varies according to a second process condition, and configured to supply the second bulk voltage to a body of at least one second MOS transistor included in a second internal circuit.

13. The memory device of claim 12, wherein:
the first core die in the first process condition that is a condition in which a fast operation is performed; and
the second core die in the second process condition that is a condition in which a slow operation is performed.

14. The memory device of claim 13, wherein the first core die comprises:
a first target code generation circuit configured to generate a first high-temperature code and a first low-temperature code based on the first process condition;
a first temperature code generation circuit configured to generate a first common temperature code based on the first process condition;
a first temperature reference voltage generation circuit configured to generate a first temperature reference voltage at a voltage level adjusted by the first high-temperature code, the first common temperature code, and the first low-temperature code; and
a first bulk voltage generation circuit configured to generate the first bulk voltage at a voltage level adjusted based on the first temperature reference voltage.

15. The memory device of claim 14, wherein the first target code generation circuit is configured to:
generate the first high-temperature code that is a binary bit set used to adjust the first bulk voltage in a high-temperature condition for which an internal temperature is identified for adjustment; and
generate the first low-temperature code that is a binary bit set used to adjust the first bulk voltage in a low-temperature condition for which an internal temperature is identified for adjustment.

16. The memory device of claim 14, wherein the first temperature reference voltage generation circuit comprises:
a first reference voltage generation circuit configured to generate a first reference voltage that is adjusted based on the first high-temperature code;
a first voltage selection unit configured to generate a plurality of first internal division voltages by dividing a voltage between a first node at the first reference voltage and a second node and configured to select one of the plurality of first internal division voltages as the first temperature reference voltage based on the first temperature code; and
a first low-temperature trimming current source connected between the second node and a ground voltage and configured to generate the first temperature-variable current based on the first low-temperature code.

17. The memory device of claim 16, wherein the first reference voltage generation circuit comprises:
a first flat reference voltage generation circuit configured to generate a first flat reference voltage at a constant voltage level based on the source voltage;
a first high-temperature trimming circuit configured to output the first flat reference voltage as a first internal reference voltage by adjusting the first flat reference voltage based on the first high-temperature code;
a first comparator configured to activate a first pull-up signal by comparing the first internal reference voltage and a first reference voltage; and
a first internal voltage driving circuit configured to drive the first reference voltage to a voltage level of the source voltage when the first pull-up signal is activated.

18. The memory device of claim 14, wherein the first bulk voltage generation circuit comprises:
a first bulk voltage comparator configured to generate a first bulk pull-up signal by comparing the first temperature reference voltage and a first feedback voltage;
a first bulk voltage driving circuit configured to drive the first bulk voltage to a voltage level of an external voltage when the first bulk pull-up signal is activated and configured to output the first bulk voltage; and
a first feedback voltage generation circuit configured to generate the first feedback voltage that varies based on the first bulk voltage.

19. The memory device of claim 13, wherein the second core die comprises:
a second target code generation circuit configured to generate the second high-temperature code and the second low-temperature code based on the second process condition;
a second temperature code generation circuit configured to generate a second common temperature code based on the second process condition;
a second temperature reference voltage generation circuit configured to generate a second temperature reference voltage at a voltage level adjusted by the second high-temperature code, the second common temperature code, and the second low-temperature code; and
a second bulk voltage generation circuit configured to generate the second bulk voltage at a voltage level adjusted based on the second temperature reference voltage.

20. The memory device of claim 19, wherein the second target code generation circuit is configured to:
generate the second high-temperature code that is a binary bit set used to adjust the second bulk voltage in a high-temperature condition for which an internal temperature is identified for adjustment; and
generate the second low-temperature code that is a binary bit set used to adjust the second bulk voltage in a low-temperature condition for which an internal temperature is identified for adjustment.

21. The memory device of claim 19, wherein the second temperature reference voltage generation circuit comprises:
a third reference voltage generation circuit configured to generate a third reference voltage based on the second high-temperature code;
a second voltage selection unit configured to generate a plurality of second internal division voltages by dividing a voltage between the third node at a third reference voltage and a fourth node at a fourth voltage and configured to select one of the plurality of second internal division voltages as the second temperature reference voltage based on the second temperature code; and
a second low-temperature trimming current source connected between the fourth node and a ground voltage and configured to generate a second temperature-variable current based on the second low-temperature code.

22. The memory device of claim 21, wherein the second temperature reference voltage generation circuit comprises:
a second flat reference voltage generation circuit configured to generate a second flat reference voltage at a constant voltage level based on a source voltage;
a second high-temperature trimming circuit configured to output the second flat reference voltage as a second internal reference voltage by adjusting the second flat reference voltage based on the second high-temperature code;
a second comparator configured to generate a second pull-up signal by comparing the second internal reference voltage and a third reference voltage; and
a second internal voltage driving circuit configured to drive the third reference voltage to a voltage level of the source voltage when the second pull-up signal is activated.

23. The memory device of claim 19, wherein the second bulk voltage generation circuit comprises:
a second bulk voltage comparator configured to generate a second bulk pull-up signal by comparing the second temperature reference voltage and a second feedback voltage;
a second bulk voltage driving circuit configured to drive the second bulk voltage to a voltage level of an external voltage when the second bulk pull-up signal is activated and configured to output the second bulk voltage; and
a second feedback voltage generation circuit configured to generate the second feedback voltage that varies based on the second bulk voltage.
